(19) United States
(12) Patent Application Publication
(10) Pub. No.: US 2008/0153188 A1
(43) Pub. Date: Jun. 26, 2008

(54) APPARATUS AND METHOD FOR FORMING SEMICONDUCTOR LAYER

(76) Inventors: Hiroshi Ohki, Tokyo (JP); Yoshiharu Nakajima, Chiba (JP)

Correspondence Address: BIRCH STEWART KOLASCH & BIRCH, PO BOX 747, FALLS CHURCH, VA, 22040-0747, US

(21) Appl. No.: 11/961,041

(22) Filed: Dec. 20, 2007

(30) Foreign Application Priority Data
Dec. 22, 2006 (JP) 2006-346737

(51) Int. Cl. H01L 21/00

(52) U.S. Cl. 438/21; 257/E21.001

(57) ABSTRACT

Grooves forming a thin-film transistor (TFT) pattern are formed on the surface of a roller. A tank supplies ink including semiconductor materials to the roller. A squeegee embeds the ink supplied to the roller into the grooves formed on the surface thereof. The roller transfers the ink embedded in the grooves onto a substrate. With this arrangement, the processing time for forming substrates is shortened.

This nonprovisional application claims priority under 35 U.S.C. § 119(a) on Patent Application No. 346737/2006 filed in Japan on Dec. 22, 2006, the entire contents of which are hereby incorporated by reference.

### FIELD OF THE INVENTION

The present invention relates to a semiconductor layer forming apparatus and a method for forming a semiconductor layer.

### BACKGROUND OF THE INVENTION

Flat panel displays (FPD) such as liquid crystal displays, organic EL (electroluminescence) displays, and inorganic EL displays are categorized into a passive matrix display and an active matrix display according to a driving method. The passive matrix display employs a passive driving method, and the active matrix display employs an active driving method.

The passive matrix display has a positive electrode (column) and a negative electrode (row) provided in a matrix fashion. A scanning signal is fed to a selected row electrode from a row driver circuit. A data signal for each pixel is fed to a column electrode from a column driver circuit.

On the other hand, the active matrix display controls an input signal for each pixel through a thin-film transistor. Therefore, the active matrix display is suitable for FPDs used for video displays, which requires to process a large volume of signals.

The following briefly describes a thin-film transistor used for the active matrix display. A thin-film transistor includes: a source and a drain into which concentrated impurities are doped; a channel which is formed between the source and the drain; a gate electrode which switches on and off the channel; and an insulating film which isolates the channel from the gate electrode.

Conventionally, amorphous silicon or polysilicon was used for the channel of the thin-film transistor. Recently, polysilicon has been frequently used because polysilicon is more excellent in electrical characteristic and reliability, applicability to large-area electronics, and the like. However, unfortunately, a grain size of polysilicon is as large as several hundred nanometers (nm). This gives rise to the problems including reduction in electrical properties and reliability of a miniaturized thin-film transistor.

One of the solutions to the problem associated with such a thin-film transistor made of polysilicon is to use nanostructures in a transistor. However, in order to form a nanodevice with nanostructures, the nanostructures need to be precisely oriented to a source electrode, a drain electrode, or a gate electrode of the transistor, which is a minimal unit of the nanodevice. There are various methods as a method for controlling orientation of such nanostructures.

Japanese Unexamined Patent Publication No. 2005-169614 (published on Jun. 30, 2005; hereinafter referred to as Patent Document 1) discloses a method for controlling orientation of carbon nanotubes, which are a kind of the nanostructures. According to the method, a plurality of grooves is formed on the surface of a substrate placed on a stage. A width of an open end of each groove is formed to be larger than a diameter of the carbon nanotube, and shorter than a length of the carbon nanotube. Ink in which the carbon nanotubes are dispersed is applied on this substrate. The substrate on which the ink is applied is swept with a squeegee, so that the carbon nanotubes as well as the ink are fallen into each groove. This allows the carbon nanotubes to be oriented in longitudinal directions of the grooves. The ink is heat-treated so that a solvent in the ink is vaporized. In this way, the carbon nanotubes are oriented along the grooves on the substrate.

However, in the method disclosed in Patent Document 1, the grooves are formed on the surface of the substrate placed on the stage, and the ink in which the carbon nanotubes are dispersed is applied thereon. The method therefore requires the steps of placing the substrate to be processed, washing the squeegee to sweep the ink and the stage to which extra ink is adhered, and the like steps. This makes the substrate treatment process complicated. As a result, the processing time becomes longer.

The present invention is accomplished to solve the problems discussed above. An object of the present invention is to provide a semiconductor layer forming apparatus and a method for forming a semiconductor layer, in which a semiconductor layer is formed on a surface of a substrate by transferring ink onto the surface of the substrate, the ink including semiconductor materials and being embedded in grooves forming a pattern of the semiconductor layer, whereby the processing time for forming substrates is shortened.

### SUMMARY OF THE INVENTION

In order to achieve the above object, a semiconductor layer forming apparatus in accordance with the present invention includes: first ink transfer means which has grooves formed on a surface thereof, the grooves forming a pattern of a semiconductor layer; ink supplying means which supplies ink to the first ink transfer means, the ink including semiconductor materials; and ink embedding means which embeds the ink supplied to the first ink transfer means into the grooves, the first ink transfer means directly or indirectly transferring the ink embedded into the grooves onto a surface of a substrate so that the semiconductor layer is formed on the surface of the substrate.

With this configuration, the grooves forming a pattern of the semiconductor layer are formed on the surface of the first ink transfer means. The ink supplying means supplies the ink to the first ink transfer means. This ink at least includes semiconductor materials. The ink supplied to the first ink transfer means by the ink supplying means is embedded into the grooves formed on the surface of the first ink transfer means by the ink embedding means. The first ink transfer means directly or indirectly transfers the ink embedded into this grooves onto the surface of the substrate. Thus, the semiconductor layer is formed on the surface of the substrate.

In this way, by transferring the ink forming the pattern of the semiconductor layer onto the substrate, the semiconductor layer is formed on the surface of the substrate. This enables the processing time for forming substrates to be shortened.

In order to achieve the above object, a method for forming a semiconductor layer in accordance with the present invention includes the steps of: supplying ink including semiconductor materials to first ink transfer means which has grooves formed on a surface thereof, the grooves forming a pattern of a semiconductor layer; embedding the ink supplied to the first ink transfer means into the grooves; and directly or indirectly transferring the ink embedded into the grooves onto a surface of a substrate so that the semiconductor layer is formed on the surface of the substrate.

The above configuration brings the same advantageous effect as that of the semiconductor layer forming apparatus in accordance with the present invention.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1A is a view schematically illustrating a thin-film transistor manufacturing apparatus in accordance with First embodiment of the present invention. FIG. 1B is a view illustrating how ink is transferred onto a substrate.

FIG. 2A is a perspective view illustrating a roller in accordance with First embodiment of the present invention. FIG. 2B is a perspective view illustrating one of grooves forming a thin-film transistor (TFT) pattern on the surface of the roller.

FIG. 3 is a view schematically illustrating a thin-film transistor manufacturing apparatus in accordance with Second embodiment of the present invention.

FIG. 4A is a view illustrating semiconductor material arrangement areas formed on the surface of a substrate. FIG. 4B is a view illustrating anisotropic semiconductor materials which are transferred onto a substrate from a belt, and are not oriented by an orientation control device. FIG. 4C is a view illustrating anisotropic semiconductor materials which are oriented by an orientation control device 34.

### DESCRIPTION OF THE EMBODIMENTS

### First Embodiment

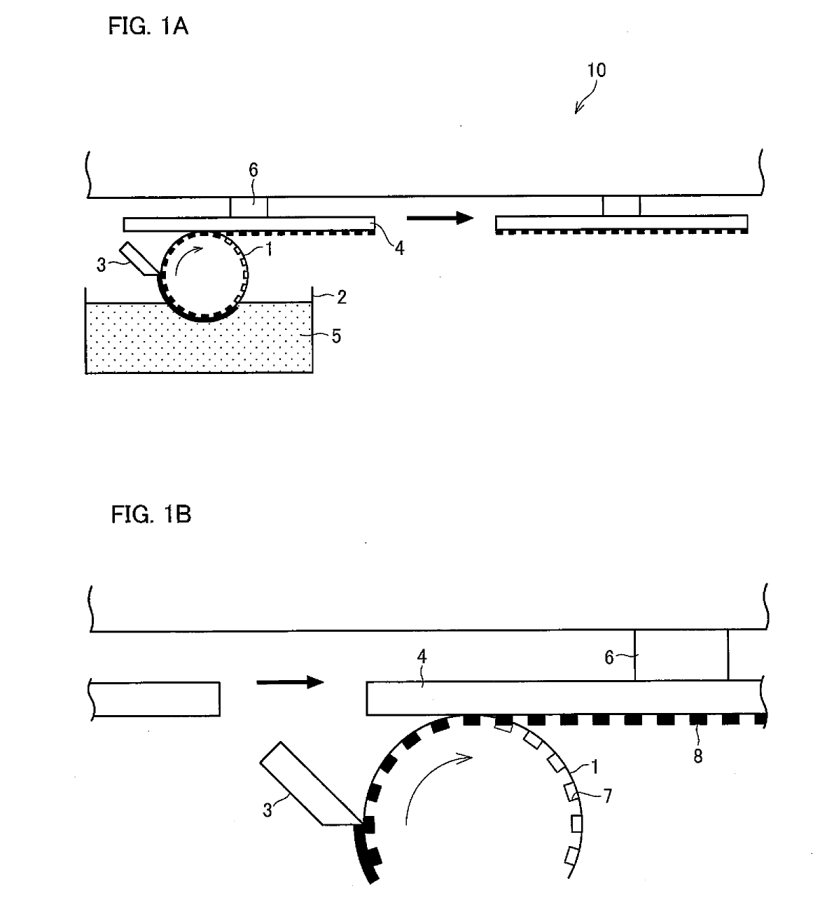

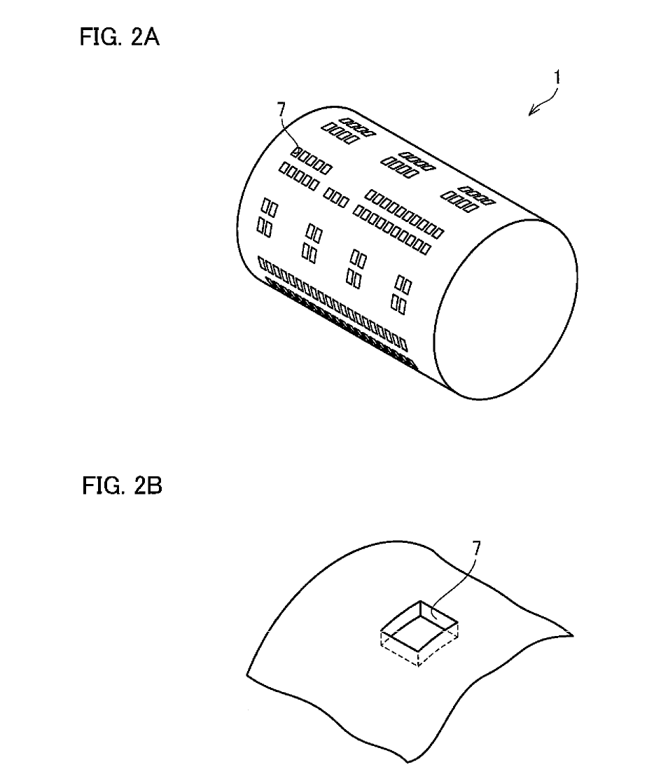

The first embodiment of the present invention is described hereinafter with reference to FIG. 1A, FIG. 1B, FIG. 2A and FIG. 2B.

[Configuration of a Thin-Film Transistor Manufacturing Apparatus 10]

The following is an explanation about a thin-film transistor manufacturing apparatus 10 (a semiconductor layer forming apparatus) with reference to FIG. 1A and FIG. 1B. FIG. 1A is a view schematically illustrating a configuration of a thin-film transistor manufacturing apparatus 10 in accordance with the first embodiment of the present invention. As illustrated in FIG. 1A, the thin-film transistor manufacturing apparatus 10 includes a roller 1 (first ink transfer means), a tank 2 (ink supplying means), a squeegee 3 (ink embedding means), and a substrate conveyor 6.

Grooves 7 forming a semiconductor layer pattern are formed on a surface of the roller 1. In the present embodiment, the grooves 7 formed on the surface of the roller 1 and forming the pattern of the semiconductor layer define a pattern of a thin-film transistor (TFT). However, the grooves 7 may define other semiconductor layer patterns. The tank 2 stores ink 5 and supplies the ink 5 to the roller 1. The ink 5 includes semiconductor materials. The squeegee 3 embeds the ink 5 supplied from the tank 2 into the grooves 7 formed on the surface of the roller 1. The roller 1 directly transfers the embedded ink 5 onto a substrate 4. In this way, the semiconductor layer is formed on the surface of the substrate 4. The substrate 4 is fixed to the thin-film transistor manufacturing apparatus 10 through the substrate conveyor 6. The substrate conveyor 6 carries the substrate 4 at a speed in accordance with a speed at which the ink 5 is transferred onto the substrate 4 from the roller 1.

(Roller 1)

The roller 1 in accordance with the present embodiment is in the shape of a cylinder, and the grooves 7 forming the TFT pattern are formed on the surface thereof. FIG. 2A and FIG. 2B illustrate an example of the roller 1. FIG. 2A is a perspective view of the roller 1 in accordance with the first embodiment of the present invention. FIG. 2B is a perspective view illustrating part of the grooves 7 forming the TFT pattern formed on the surface of the roller 1. As illustrated in FIG. 2A, the grooves 7 forming the TFT pattern are formed on the surface of the roller 1. The pattern formed by the grooves 7 on the roller 1 can be deleted, and another grooves 7, which define other semiconductor layer patterns, can be formed. Thus, various semiconductor layers can be easily formed, and production cost of substrates can be reduced.

A width and a perimeter of the roller 1 are adjusted to a size of a TFT pattern to be formed on the surface of the substrate 4. That is, the size of the roller 1 is adjusted as the ink defining a desired TFT pattern is transferred exactly onto the surface of one substrate 4 when the roller 1 goes into a 360-degree roll on the surface of the substrate 4.

The squeegee 3 embeds the ink 5 into the grooves 7 forming the TFT pattern in FIG. 2B, which are formed on the surface of the roller 1. The size of each one of the grooves 7 is accordingly adjusted depending on the density, viscosity, or the like of the ink 5.

(Tank 2)

The tank 2 supplies the ink 5 to the roller 1. The ink includes semiconductor materials. As illustrated in FIG. 1A and FIG. 1B, the tank 2 in the first embodiment is a container storing the ink 5. When the roller 1 comes into contact with the ink 5 in the tank 2, the ink 5 is supplied to the roller 1. More specifically, the roller 1 is arranged at such a position that the surface of the roller 1 comes into contact with the ink 5 in the container. The density, viscosity, or the like of the ink 5 is adjusted so that a desired amount of the ink 5 is supplied to the roller 1. In order to supply the ink 5 to the entire circumstance of the surface of the roller 1, the roller 1 is rotated with its surface in contact with the ink 5. The tank 2 may be an ink jet device which emits the ink 5 in droplets to the roller 1 so that the ink 5 is supplied to the roller 1.

(Squeegee 3)

The squeegee 3 embeds the ink 5 which is supplied to the roller 1 from the tank 2 into the grooves 7 forming the TFT pattern. As illustrated in FIG. 1A and FIG. 1B, the squeegee 3 is a spatular shape, and sweeps the surface of the roller 1 at a lower end of the squeegee 3. Thus, the ink 5 is embedded into the grooves 7 formed on the surface of the roller 1.

(Transfer of the Ink 5)

The following is an explanation about steps of transferring the ink 5 embedded into the grooves 7 onto the substrate 4 with reference to FIG. 1B. The grooves 7 are formed on the surface of the roller 1, forming the TFT pattern. FIG. 1B is a view schematically illustrating the thin-film transistor manufacturing apparatus 10 in accordance with the first embodiment of the present invention. FIG. 1B also illustrates how the ink 5 embedded into the grooves 7 on the roller 1 is transferred onto the substrate 4.

As illustrated in FIG. 1B, the ink 5 supplied to the roller 1 is embedded into the grooves 7 formed on the surface of the roller 1 by the squeegee 3. At this time, the squeegee 3 wipes off the extra ink 5 supplied to areas other than the grooves 7 on the roller 1. Consequently, when the ink 5 is transferred onto the substrate 4 from the roller 1, only the ink 5 embedded into the grooves 7 is transferred onto the substrate 4. In this way, ink 8 defining a desired TFT pattern can be transferred onto the substrate 4.

The roller 1 transfers the ink 5 embedded into the grooves 7 on the surface thereof onto the substrate 4. The roller 1 is arranged at a position such that the roller 1 can rotationally move with its surface in contact with the substrate 4 which is carried by the substrate conveyor 6. The roller 1 comes into contact with the substrate 4 under appropriate pressure to transfer the ink 5 embedded into the grooves 7 onto the substrate 4. The appropriate pressure to transfer the ink 5 onto the substrate 4 is adjusted in consideration of the viscosity or the like of the ink 5 embedded into the grooves 7. In order to continuously transfer the ink 5 from the roller 1 onto the substrate 4, the substrate conveyor 6 continuously carries the substrate 4 at a speed in accordance with a speed at which the ink 5 is transferred.

The roller 1 rotationally moves in the same direction as the substrate conveyor 6 carries the substrate 4. The roller 1 transfers the ink 5 embedded into the grooves 7 onto the substrate 4 by rotationally moving with the surface thereof in contact with the substrate 4. By the roller 1 going into a 360-degree roll with the surface thereof in contact with the substrate 4, the ink 8 defining the TFT pattern is transferred onto the substrate 4. Thereafter, the substrate 4 is carried by the substrate conveyor 6. Then, the process proceeds to the next step.

After the roller 1 transfers the ink 5 onto the substrate 4, the tank 2 further supplies the ink 5 to the roller 1 so that the roller 1 transfers the ink 5 onto a subsequent substrate 4. The substrate conveyor 6 carries the subsequent substrate 4 onto which the ink 5 is to be transferred. The roller 1 rotationally moves with the surface thereof in contact with the surface of the subsequent substrate 4. Thus, when the ink 5 is supplied to the roller 1 again, the roller 1 transfers the ink 5 onto the subsequent substrate 4 carried by the substrate conveyor 6.

In this way, the steps of supplying the ink 5, embedding the ink 5 into the grooves on the roller, and transferring the ink 5 onto the substrate 4 are performed successively while the roller 1 is being rotated, so that the ink 5 is continuously transferred onto the substrate 4. This allows a semiconductor layer to be formed on the surface of the substrate 4, thus shortening the processing time for forming substrates.

### Second Embodiment

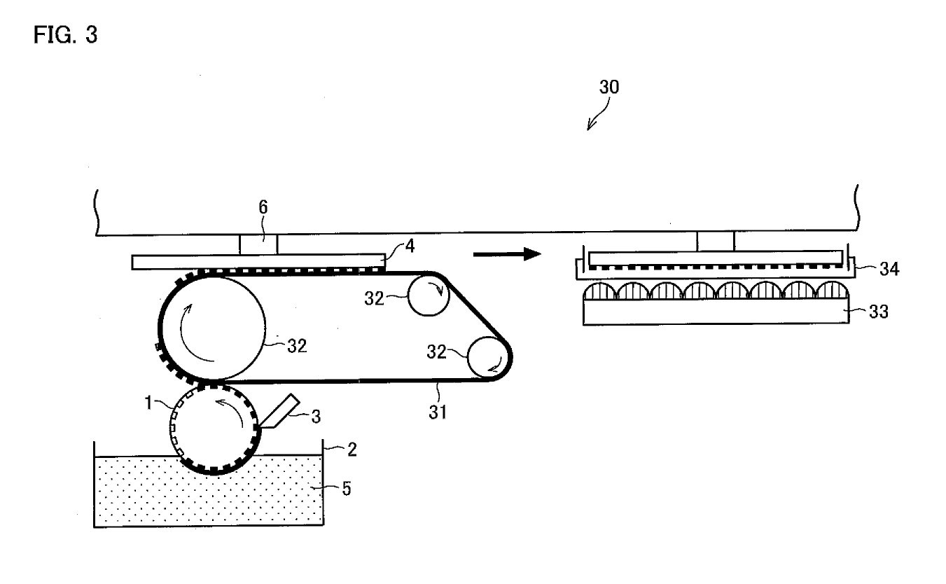

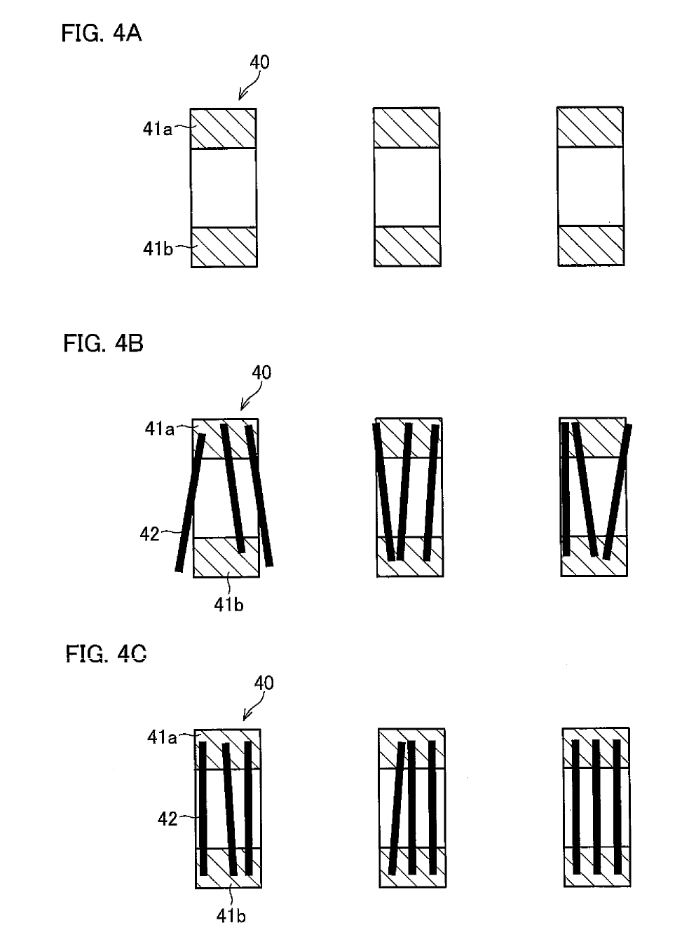

Another embodiment of the present invention is described hereinafter with reference to FIG. 3, FIG. 4A and FIG. 4B.

(Thin-Film Transistor Manufacturing Apparatus 30)

A thin-film transistor manufacturing apparatus 30 (semiconductor layer forming apparatus) in accordance with the second embodiment of the present invention is described as below with reference to FIG. 3. FIG. 3 is a view schematically illustrating a configuration of a thin-film transistor manufacturing apparatus 30 in accordance with the second embodiment of the present invention. As illustrated in FIG. 3, the thin-film transistor manufacturing apparatus 30 includes a roller 1, a tank 2, a squeegee 3, a substrate conveyor 6, a belt 31 (second ink transfer means), auxiliary rollers 32, a heater 33 (ink hardening means), and an orientation control device 34 (orientation control means).

Grooves forming a TFT pattern are formed on the surface of the roller 1. The tank 2 supplies the ink 5 to the roller 1. In the second embodiment of the present invention, semiconductor materials in the ink 5 are anisotropic semiconductor materials. The squeegee 3 embeds the ink 5 supplied from the tank 2 into the grooves formed on the surface of the roller 1. The roller 1 once transfers the ink 5 embedded into the grooves onto the belt 31 before the ink 5 is transferred onto the substrate 4. The auxiliary rollers 32 rotate the belt 31 with the belt 31 in contact with the surface of the substrate 4. By rotationally moving on the surface of the substrate 4, the belt 31 transfers the ink 5 transferred thereon onto the substrate 4. The substrate 4 is fixed to the thin-film transistor manufacturing apparatus 30 through the substrate conveyor 6. The substrate conveyor 6 carries the substrate 4 at a speed, in accordance with a speed at which the ink 5 is transferred onto the substrate 4 from the roller 1.

(Materials of Ink 5)

In the second embodiment, the ink 5 supplied from the tank 2 includes anisotropic semiconductor materials. Typical anisotropic semiconductor materials are, for example, carbon nanotubes. The carbon nanotubes have high anisotropic property. In order to effectively take the advantage of the anisotropic property of the carbon nanotubes, a plurality of the carbon nanotubes is required to be oriented in one direction. The thin-film transistor manufacturing apparatus 30 transfers the ink 5 including the anisotropic semiconductor materials such as the carbon nanotubes onto the surface of the substrate 4. As a result, a semiconductor layer including the anisotropic semiconductor materials is formed on the surface of the substrate 4.

When embedded into the grooves of the roller 1 by the squeegee 3, the semiconductor materials included in the ink 5 are almost completely oriented in the sweeping direction. After the ink 5 is transferred onto the substrate 4, the heater 33 hardens the ink 5. At this time, the anisotropic semiconductor materials included in the ink are further oriented by the orientation control device 34. In such steps of forming the semiconductor layer on the surface of the substrate 4, the anisotropic semiconductor materials are oriented several times. This makes it possible to form on the surface of the substrate 4 the semiconductor layer including the anisotropic semiconductor materials of which orientation are more precisely controlled.

In the second embodiment, the semiconductor materials are preferably nanowires, nanotubes, or nanorods with diameter on the order of a nanometer. Other semiconductor materials are also applicable if the semiconductor materials have anisotropy property and are in the shape of a pole, a rod, a needle, or the like, and have a few nanometers to several hundreds nanometers in diameter. More specifically, the diameter is in the range from 1 to 999 nanometers. Moreover, as such anisotropic semiconductor materials, semiconductor materials which are a few micrometers to several dozen micrometers long are also applicable. In this way, the semiconducting layers, which have various physical properties originating in the specific structures of these semiconductor materials, are formed on the surface of the substrate.

The ink 5 including such semiconductor materials is used as a dispersant which disperses these semiconductor materials. Electrically conductive ink and isolating resin ink or solvent can be used as a dispersant, too. However, the dispersant is preferably a surface-active agent having high dispersibility. A nonionic surface-active agent is more preferable because alkali ions are not included therein.

(Transfer of Ink 5)

The thin-film transistor manufacturing apparatus 30 transfers the ink 5 onto the substrate 4 as in the first embodiment of the present invention. The following is an explanation about only different parts from the first embodiment.

As illustrated in FIG. 3, the ink 5 supplied from the tank 2 to the roller 1 is embedded into the grooves forming the TFT pattern formed on the surface of the roller 1 by the squeegee 3. When the squeegee 3 embeds the ink 5 supplied to the roller 1 into the grooves, the anisotropic semiconductor materials in the ink 5 are almost completely oriented in the sweeping direction of the squeegee 3. At this time, the anisotropic semiconductor material in the ink 5 may not be fully oriented. The anisotropic semiconductor material may be oriented in the sweeping direction of the squeegee 3 to some extent.

By sweeping the ink 5 along the surface of the roller 1, the squeegee 3 wipes off to collect extra ink supplied to areas other than the grooves on the surface of the roller 1. The extra ink 5 wiped off and collected by the squeegee 3 falls into the tank 2 toward the direction of gravitational force. The tank 2 receives the falling extra ink 5. The extra ink 5, which is wiped off and collected by the squeegee 3 and received by the tank 2, is used for resupply to the roller 1. Thus, the ink is not wasted and an amount of the ink to be used decreases. Especially, the anisotropic semiconducting materials in the ink 5 are costly. So, by decreasing the amount of the ink to be used, production cost of substrates can be lowered.

In the second embodiment, the roller 1 transfers the ink 5 embedded into the grooves on the surface thereof onto the belt 31 before the ink 5 is transferred onto the substrate 4. As illustrated in FIG. 3, the belt 31 is a band-shaped belt conveyor which rotates about the auxiliary rollers 32. The belt 31 rotationally moves in contact with the surface of the roller 1. The belt 31 rotationally moves on the surface of the roller 1 so that the ink 5 embedded in the grooves of the roller 1 is transferred onto the belt 31.

The belt 31 is arranged so that the belt 31 can rotate in contact with the substrate 4 which is carried by the substrate conveyor 6. The belt 31 comes into contact with the substrate 4 under appropriate pressure to transfer the ink 5 on the belt 31 onto the substrate 4. The appropriate pressure to transfer the ink 5 onto the substrate 4 is adjusted depending on the viscosity or the like of the ink 5. In order to continuously transfer the ink 5 onto the substrate 4 from the belt 31, the belt 6 continuously carries the substrate 4 at a certain speed in accordance with a speed at which the ink 5 is transferred.

The auxiliary rollers 32 rotate the belt 31 in the direction where the substrate conveyor 6 carries the substrates 4. The belt 31 rotationally moves in contact with the surface of the substrate 4 so that the ink 5 on the belt 31 is transferred onto the substrate 4.

Thus, the speed at which the thin-film transistor manufacturing apparatus 30 transfers ink 5 onto the substrate 4 can be controlled by the rotation speed of the belt 31. The rotation speed of the belt 31 is controlled by appropriately adjusting the viscosity of the ink 5 to be transferred onto the substrate 4. That is, when the speed to transfer the ink 5 onto the substrate 4 is accelerated, the processing time for forming a semiconducting layer on the surface of the substrate 4 is shortened. Thus, the processing time to form the substrate 4 is shortened.

(Hardening of Ink)

The heater 33 hardens the ink 5 transferred onto the substrate 4 from the belt 31. By hardening the ink 5 transferred onto the surface of the substrate 4, the ink 5 is firmly fixed on the surface of the substrate 4. At the same time, an extra solvent in the ink 5 can be vaporized. The heater 33 may be a dryer which hardens the ink 5 by heating the substrate 4, or a device which irradiates the substrate 4 with ultraviolet, electron ray, or the like.

(Orientation Control of Anisotropic Semiconductor Materials)

The orientation control device 34 aligns the anisotropic semiconductor materials in the ink 5 transferred on the substrate 4 in one direction. As described above, the anisotropic semiconductor materials in the ink 5 is oriented in the sweeping direction of the squeegee 3 when the ink 5 is embedded into the grooves of the roller 1 by the squeegee 3. However, the orientation of the anisotropic semiconductor materials can be insufficiently controlled. For this reason, after the ink 5 is transferred onto the substrate 4, the orientation control device 34 controls the orientation of the anisotropic semiconductor materials in the ink 5 again.

The orientation control device 34 for such semiconductor materials can apply electric field, or magnetic field on the substrate 4 in the conventionally known method. For example, electric field is applied to the substrate 4 in order to electrophorese the anisotropic semiconductor materials in the ink 5. This orients the anisotropic semiconductor materials in such a manner that the length of the anisotropic semiconductor material is parallel to the electric field. Alternatively, magnetic field is applied to the substrate 4, whereby the anisotropic semiconductor material is oriented in such a manner that the length of the anisotropic semiconductor material is parallel to the magnetic field lines (substantially perpendicular to a conductive electrode section).

In the second embodiment, the anisotropic semiconductor materials in the ink 5 are oriented in the sweeping direction of the squeegee 3 when embedded in the grooves of the roller 1 by the squeegee 3. After the ink 5 is transferred onto the substrate 4, the anisotropic semiconductor materials in the ink 5 are oriented again by the orientation control device 34. In this way, the anisotropic semiconductor materials can be sufficiently oriented, and a high-performance semiconductor layer which effectively takes the advantage of the properties of the anisotropic semiconductor materials can be formed on the surface of the substrate 4.

FIG. 4A, FIG. 4B, and FIG. 4C illustrate the steps of controlling the orientation of anisotropic semiconductor materials 42 in the ink 5 transferred onto the substrate 4. FIG. 4A, FIG. 4B, and FIG. 4C are views schematically illustrating how the orientation of the anisotropic semiconductor materials 42 is controlled. As illustrated in FIG. 4A, a semiconductor material arrangement area 40 is formed on the substrate 4. The semiconductor material arrangement area 40 includes a source area 41a and a drain area 41b. The source area 41a and drain area 41b are preferably made of material which can fix the anisotropic semiconductor materials 42. For example, electrically conductive ink is screen-printed in a desired pattern and heated by the heater 33, so that the electrically conductive ink is printed on the surface of the substrate 4.

FIG. 4B is a view illustrating the anisotropic semiconductor materials 42 transferred onto the substrate 4 from the belt 31. In FIG. 4B, the anisotropic semiconductor materials 42 are not oriented by the orientation control device 34. As illustrated in FIG. 4B, some of the anisotropic semiconductor materials 42 are out of the semiconductor material arrangement area 40, and are not sufficiently oriented. Besides, the anisotropic semiconductor materials 42 are insufficiently in contact with the source area 41a and the drain area 41b.

FIG. 4C is a view illustrating the anisotropic semiconductor materials 42 after oriented by the orientation control device 34. As illustrated in FIG. 4C, all the anisotropic semiconductor materials 42 are oriented within the semiconductor material arrangement area 40. Furthermore, all the anisotropic semiconductor materials 42 are fully in contact with the source area 41a and drain area 41b. These source area 41a and drain area 41b are made of the electrically conductive ink so that the anisotropic semiconductor materials 42 can be fixed within the semiconductor material arrangement area 40. Thus, the orientation of the anisotropic semiconductor materials 42 can be sufficiently controlled, and herewith a high-performance semiconductor layer can be formed on the surface of the substrate 4.

The present invention is not limited to the description of the embodiments above, but may be altered by a skilled person within the scope of the claims. An embodiment based on a proper combination of technical means disclosed in different embodiments is encompassed in the technical scope of the present invention.

(Other Configuration)

The present invention can be also described as below.

(First Configuration)

A thin-film transistor manufacturing apparatus including: a sample tank which stores ink including nanostructures; a first roller onto which the ink is supplied from the sample tank; a squeegee which sweeps off extra ink deposited onto the first roller; a roll onto which the ink on the first roller is transferred after the extra ink is swept off by the squeegee; a second roller which applies the ink transferred onto the roll to a support substrate under pressure; auxiliary rollers which rotate the roll; and a dryer which dries off the support substrate.

(Second Configuration)

The thin-film transistor manufacturing apparatus as set forth in the first configuration, in which a desired pattern is arranged on the first roller.

(Third Configuration)

The thin-film transistor manufacturing apparatus as set forth in the first configuration, in which the drier includes an orientation control device.

(Forth Configuration)

The thin-film transistor manufacturing apparatus as set forth in the first configuration, in which the squeegee is a blade or a knife.

(Fifth Configuration)

The thin-film transistor manufacturing apparatus as set forth in any one of the first through fourth configurations, in which the ink is made of nanoscale materials such as nanowires, nanotubes, nanorods, or the like.

(Sixth Configuration)

A method for forming a thin-film transistor, including the steps of: (a) embedding ink into grooves forming a desired pattern; (b) transferring an ink pattern embedded into the grooves; (c) applying the thus transferred ink pattern to a substrate under pressure; and (d) drying off the applied ink pattern.

(Seventh Configuration)

The method for forming a thin-film transistor as set forth in the sixth configuration, in which rotational movement is performed in the step (c).

(Eighth Configuration)

The method for forming a thin-film transistor as set forth in the sixth configuration, in which orientation control is performed in the step (a).

(Ninth Configuration)

The method for forming a thin-film transistor as set forth in the sixth configuration, in which orientation control is performed in the step (d).

(Tenth Configuration)

The method for forming a thin-film transistor as set forth in the eighth or ninth configuration, in which orientation of nanostructures in the ink is controlled in a stepwise fashion.

As described above, a semiconductor layer forming apparatus in accordance with the present invention forms a semiconductor layer on a surface of a substrate by transferring ink onto the surface of the substrate, so that the semiconductor layer can be continuously formed. The ink includes semiconductor materials and is embedded in grooves forming the pattern of the semiconductor layer pattern. As a result, the processing time for forming a semiconductor layer can be shortened.

The present invention is applicable to manufacture of a semiconductor device including a substrate on which semiconductor layers are mounted. Especially, the present invention can be preferably used as an apparatus for manufacturing a thin-film transistor which is used for flat panel displays such as a liquid crystal display, organic EL (electroluminescence) display, or the like.

It is preferable that the semiconductor layer forming apparatus in accordance with the present invention further includes second ink transfer means, the first ink transfer means transferring the ink embedded into the grooves onto the surface of the second ink transfer means, and the second ink transfer means forming the semiconductor layer on the surface of the substrate by transferring the ink onto the surface of the substrate.

With this configuration, the first ink transfer means transfers the ink embedded into the grooves forming the semiconductor layer pattern on the surface of the first ink transfer means onto the second ink transfer means before transferring the ink on the substrate. The second ink transfer means transfers the ink which has been transferred from the first ink transfer means onto the surface of the substrate. Thus, the semiconductor layer is formed on the surface of the substrate.

In this way, for example, when the second ink transfer means is in the shape of a roll, the second ink transfer means transfers the ink onto the surface of the substrate while rotating with the surface thereof in contact with the surface of the substrate. With the second ink transfer means rotating, the ink can be continuously transferred on the surface of the substrates. As a result, the processing time for forming substrates can be shortened.

It is preferable that the semiconductor layer forming apparatus in accordance with the present invention further includes substrate carrying means which carries the substrates. With this configuration, the substrate carrying means continuously carries the substrates at a speed in accordance with a speed at which the ink is transferred. This makes it possible to eliminate the need for the step of placing substrates. It is also possible to continuously transfer the ink on the substrate while the substrate is carried. As a result, the processing time for forming a semiconductor layer can be shortened.

In the semiconductor layer forming apparatus in accordance with the present invention, it is preferable that the first ink transfer means transfers the ink embedded into the grooves onto the surface of the substrate while rotating with the surface thereof in contact with the surface of the substrate. With this configuration, the first ink transfer means rotationally moves with the surface thereof in contact with the surface of the substrate. Thus, the ink embedded into the grooves formed on the surface of the first ink transfer means is continuously transferred onto the surface of the substrate with the first ink transfer means rotating. This enables the processing time for forming substrates to be shortened.

Moreover, in the semiconductor layer forming apparatus, it is preferable that the grooves form a thin-film transistor pattern. With this configuration, the thin-film transistor is formed by transferring the ink embedded into the grooves forming the thin-film transistor pattern onto the surface of the substrate. Consequently, the thin-film transistor can be formed more easily.

In the semiconductor layer forming apparatus in accordance with the present invention, it is preferable that the substrate onto which the ink is transferred is a semiconductor substrate, a glass substrate, or a plastic substrate. With this, for example, a transistor or the like which is applicable to various electronics devices can be produced.

Recently, with the advent of ubiquitous network society, the use of wearable electronic devices such as a handheld terminal or the like, or electronic components such as a sensor or the like has gradually drawn attention. In order to provide such wearable electronic devices or components, they need to be flexible. On the other hand, in order to manufacture flexible electronic devices or components, they need to be less damaged by heating during the manufacture.

According to the semiconductor layer forming apparatus of the present invention, the semiconductor materials can be transferred on the substrate without large thermal treatment to components including the substrate. Therefore, for example, a semiconductor substrate, a low melting glass substrate, a plastic substrate (substrate made of organic materials) can be used. Moreover, a substrate provided with heat-sensitive materials, patterns, components and the like can be also used.

In the semiconductor layer forming apparatus in accordance with the present invention, it is preferable that the semiconductor materials are anisotropic semiconductor materials. This makes it possible to form a semiconductor layer including anisotropic semiconductor materials on the surface of the substrate.

In the semiconductor layer forming apparatus in accordance with the present invention, it is preferable that the semiconductor materials have a diameter on an order of a nanometer. A semiconductor layer including more microscopic semiconductor materials can be formed on the surface of the substrate. Consequently, for example, by using the substrate on which this microscopic semiconductor layer is formed, a high-performance semiconductor device can be provided. The diameter on the order of a nanometer is, for example, from 1 to 999 nanometers.

In the semiconductor layer forming apparatus in accordance with the present invention, it is preferable that the semiconductor materials are nanowires, nanotubes, or nanorods. This makes it possible to form a semiconductor layer including nanowires, nanotubes, or nanorods on the surface of the substrate. For example, by using this substrate, a semiconductor device which has various physical properties originating from the specific structures of these semiconductor materials can be produced.

In the semiconductor layer forming apparatus in accordance with the present invention, it is preferable that the ink embedding means sweeps off the surface of the first ink transfer means. Furthermore, in the semiconductor layer forming apparatus in accordance with the present invention, it is preferable that the ink embedding means is a blade or a knife.

With this configuration, the ink embedding means sweeps off the surface of the first ink transfer means. At this time, the anisotropic semiconductor materials, which are included in the ink to be embedded into the grooves formed on the surface of the first ink transfer means, are almost completely oriented in a direction where the ink embedding means sweeps. This makes it possible to form a semiconductor layer including the almost completely oriented anisotropic semiconductor materials on the surface of the substrate. For example, by using this substrate, a high-performance semiconductor can be produced.

It is preferable that the semiconductor layer forming apparatus in accordance with the present invention further includes orientation control means which controls orientation of the semiconductor materials in the ink transferred onto the substrate. With this configuration, the anisotropic semiconductor materials which are included in the ink transferred onto the surface of the substrate are almost completely oriented in the direction where the ink embedding means sweeps. The orientation control means further controls the orientation of the anisotropic semiconductor materials. Thus, a semiconductor layer in which the anisotropic semiconductor materials included in the ink are sufficiently oriented is formed on the substrate. Thus, it is possible to form a semiconductor layer which effectively takes advantage of the properties of the anisotropic semiconductor materials on the substrate.

It is preferable that the semiconductor layer forming apparatus in accordance with the present invention further includes ink hardening means, which is integrated with the orientation control means, hardens the ink transferred onto the surface of the substrate. With this configuration, the ink transferred onto the substrate is firmly fixed on the surface of the substrate, and the anisotropic semiconductor materials in the ink are oriented. Thus, it is possible to effectively orient the anisotropic semiconductor materials. Also, it is possible to shorten the processing time for forming substrates.

In the semiconductor layer forming apparatus in accordance with the present invention, it is preferable that the ink supplying means is a tank which stores the ink, and collects the extra ink wiped off from the surface of the first ink transfer means by the ink embedding means. With this configuration, the ink supplying means collects the extra ink which has not been embedded into the grooves formed on the surface of the first ink transfer means. This eliminates wasting the semiconductor materials included in the ink. As a result, an amount of the semiconductor materials to be used decreases, and production cost of the substrates can be lowered.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor layer forming apparatus, comprising:
first ink transfer means which has grooves formed on a surface thereof, the grooves forming a pattern of a semiconductor layer;
ink supplying means which supplies ink to the first ink transfer means, the ink including semiconductor materials; and
ink embedding means which embeds the ink supplied to the first ink transfer means into the grooves,
the first ink transfer means directly or indirectly transferring the ink embedded into the grooves onto the surface of the substrate so that the semiconductor layer is formed on the surface of the substrate.

2. The apparatus as set forth in claim 1, further comprising:
second ink transfer means,
the first ink transfer means transferring the ink embedded into the grooves onto a surface of the second ink transfer means, the second ink transfer means forming the semiconductor layer on the surface of the substrate by transferring the transferred ink onto the surface of the substrate.

3. The apparatus as set forth in claim 1, further comprising:
substrate carrying means which carries the substrate.

4. The apparatus as set forth in claim 1, wherein the first ink transfer means transfers the ink embedded into the grooves onto the surface of the substrate while rotating with a surface thereof in contact with the surface of the substrate.

5. The apparatus as set forth in claim 1, wherein the grooves form a thin-film transistor pattern.

6. The apparatus as set forth in claim 1, wherein the substrate onto which the ink is transferred is a semiconductor substrate, a glass substrate, or a plastic substrate.

7. The apparatus as set forth in claim 1, wherein the semiconductor materials are anisotropic semiconductor materials.

8. The apparatus as set forth in claim 7, wherein a diameter of the semiconductor materials is on an order of a nanometer.

9. The apparatus as set forth in claim 8, wherein the semiconductor materials are nanowires, nanotubes, or nanorods.

10. The apparatus as set forth in claim 1, wherein the ink embedding means sweeps off the surface of the first ink transfer means.

11. The apparatus as set forth in claim 10, wherein the ink embedding means is a blade or a knife.

12. The apparatus as set forth in claim 1, further comprising:
orientation control means which controls orientation of the semiconductor materials in the ink transferred on the substrate.

13. The apparatus as set forth in claim 12, further comprising:
ink hardening means, integrated with the orientation control means, which hardens the ink transferred onto the surface of the substrate.

14. The apparatus as set forth in claim 1, wherein the ink supplying means is a tank which stores the ink, and collects the ink wiped off from the surface of the first ink transfer means by the ink embedding means.

15. A method for forming a semiconductor layer, comprising the steps of:
supplying ink including semiconductor materials to first ink transfer means which has grooves formed on a surface thereof, the grooves forming a pattern of a semiconductor layer;
embedding the ink supplied to the first ink transfer means into the grooves; and
directly or indirectly transferring the ink embedded into the grooves onto a surface of a substrate so that the semiconductor layer is formed on the surface of the substrate.
